(19) United States
(12) Patent Application Publication
(10) Pub. No.: US 2026/0298765 A1
(43) Pub. Date: Oct. 1, 2026

(54) METHOD FOR RAPID LOCALIZATION OF DAM LEAKAGE PASSAGE BASED ON GRADIENT MEASUREMENT OF TOTAL MAGNETIC FIELD

(71) Applicant: Central South University, Changsha City (CN)

(72) Inventors: Diquan Li, Changsha City (CN); Xuefeng Chen, Changsha City (CN); Yanfang Hu, Changsha City (CN); Fu Li, Changsha City (CN)

(73) Assignee: Central South University, Changsha City (CN)

(21) Appl. No.: 19/342,814

(22) Filed: Sep. 29, 2025

(30) Foreign Application Priority Data
Mar. 25, 2025 (CN) 202510354055.0

(51) Int. Cl. G01M 3/40; G01M 3/00; G01N 27/74; G01N 27/82; G01R 33/022; G01R 35/00

(52) U.S. Cl. CPC G01M 3/40; G01M 3/007; G01N 27/74; G01N 27/82; G01R 33/022; G01R 35/005

(57) ABSTRACT

The disclosure belongs to the technical fields of water conservancy and engineering geophysical exploration. Disclosed is a method for rapid localization of a dam leakage passage based on gradient measurement of a total magnetic field. The method includes deploying a power supply electrode, and establishing a current loop; designing a gradient observation device; deploying an observation profile; calculating total magnetic field anomaly values at different observation heights, and calibrating a lateral position of a leakage passage; and calculating a longitudinal burial depth of the leakage passage. In the disclosure, the characteristic that the total magnetic field intensity generated by the leakage passage is inversely proportional to the distance is utilized to calculate a burial depth of the leakage passage and locate the leakage passage; moreover, the located leakage passage is combined with a leakage outlet on a downstream face to identify an inlet of the leakage passage.

### TECHNICAL FIELD

The disclosure relates to the technical fields of water conservancy and engineering geophysical exploration, and specifically relates to a method for rapid localization of a dam leakage passage based on gradient measurement of a total magnetic field.

### BACKGROUND

There are nearly 100,000 reservoirs and over 400,000 kilometers of river levees in China. Due to long term operations, numerous levees suffer from many complex hidden dangers that occur frequently, such as leakage, piping, and even levee breaches, causing significant losses to lives and property of people. Localization of leakage passage is crucial for preventing piping, leakage and reinforcing dams. Currently, geophysical methods used for detecting piping and leakage hazards mainly include seismic refraction method, resistivity method, transient electromagnetic method, ground-penetrating radar method, spontaneous electric field method, pseudo-flow field method, etc., of which, the pseudo-flow field method is a rapid and efficient method for detecting leakage inlets, which, on the basis of the similarity between a water flow field and a current field, establishes an artificial current field to fit the leakage water flow field, enabling the determination of flow direction and relative velocity by measuring the distribution of the current field. The traditional pseudo-flow field method mainly relies on detecting electric field components and is applied in water, requiring probes to be kept as close to the waterbed as possible. In scenarios with complex underwater environment and deep detection zones, probes are highly prone to being stuck or entangled, significantly increasing operational difficulty. Additionally, although the method can precisely locate leakage inlets, it is difficult to reflect the changing trends and direction of the leakage passage.

Therefore, there is a need to provide a method for rapid localization of a dam seepage passage based on gradient measurement of a total magnetic field.

### SUMMARY

An objective of the disclosure is to provide a method for rapid localization of a dam leakage passage based on gradient measurement of a total magnetic field, to solve the problem that the pseudo-flow field method in the prior art can only locate a leakage inlet but is difficult to reflect the changing trend and direction of the leakage passage.

To realize the above objective, the following technical solutions are employed in the disclosure.

A method for rapid localization of a dam leakage passage based on gradient measurement of a total magnetic field includes the following steps:
step S101: separately deploying a power supply electrode at an outlet of a leakage passage on a downstream face of a dam and at a position having a certain distance away from an upstream face of the dam, and applying current signals of different frequencies to establish a current loop, so as to form a current passage within the leakage passage;
step S102: designing a gradient observation device based on magnetic sensors, with an observation height difference of the magnetic sensors being Δh, and utilizing the gradient observation device to observe a magnetic field component generated by the current passage;
step S103: deploying an observation profile in a direction perpendicular to the leakage passage, and performing three-component magnetic anomaly observation using the gradient observation device;
step S104: calculating total magnetic field anomaly values at different observation heights using three-component magnetic anomaly values obtained in step S103, and calibrating a lateral position of the leakage passage on the basis of a total magnetic field anomaly intensity;
step S105: calculating a longitudinal burial depth of the leakage passage on the basis of the total magnetic field anomaly values at different observation heights corresponding to the lateral position of the leakage passage in step S104, and calibrating a longitudinal position of the leakage passage; and
step S106: determining an inlet of the leakage passage by combining the laterally calibrated position in step S104 with the longitudinally calibrated position in step S105, achieving precise localization of the leakage passage.

In an embodiment, the method for rapid localization of the dam leakage passage based on gradient measurement of the total magnetic field further includes utilizing a simultaneous transmission and reception technology to enhance anti-interference capability of data and localization accuracy on the leakage passage.

In an embodiment, steps for calibrating the lateral position of the leakage passage are as follows:
calibrating a lateral position of the current passage on the basis of spatial coordinates corresponding to maximum total magnetic field anomaly values Hₘₐₓ at different frequencies; and
steps for calibrating the longitudinal position of the leakage passage are as follows:
calculating the longitudinal burial depth of the leakage passage on the basis of total magnetic field intensity values H_{low} and H_{high} corresponding to the lateral position, with the calculation formula being as follows:

$$h = Δ h \frac{{H}_{h i g h}}{{H}_{l o w} - {H}_{h i g h}}$$

where Δh is a longitudinal height difference between two magnetic sensors, h is a burial depth of the leakage passage, H_{high} is a total magnetic field intensity measured at a higher position, and H_{low} is a total magnetic field intensity measured at a lower position.

In an embodiment, the method for rapid localization of the dam leakage passage based on gradient measurement of the total magnetic field further includes determining the inlet of the leakage passage by combining the lateral position and the longitudinal position of the leakage passage with the outlet of the leakage passage.

The disclosure has the following advantageous effects.

In the disclosure, the characteristic that the total magnetic field intensity generated by the leakage passage under the excitation of an artificial source is inversely proportional to the distance is utilized to calculate the burial depth of the leakage passage and locate the leakage passage. Moreover, the located leakage passage is combined with the leakage outlet on the downstream face, to identify the inlet of the leakage passage, making up for the deficiency that the traditional pseudo-flow field method can only locate the leakage inlet and outlet.

### BRIEF DESCRIPTION OF THE DRAWINGS

FIG. 1 is a flow chart of a method for rapid localization of a dam leakage passage based on gradient measurement of a total magnetic field according to an embodiment of the present application;

FIG. 2 is a schematic structural diagram of a method for rapid localization of a dam leakage passage based on gradient measurement of a total magnetic field according to an embodiment of the disclosure;

FIG. 3 is a schematic diagram showing a spatial positional relationship between a gradient observation device and a leakage passage according to an embodiment of the present application;

FIG. 4 is a schematic diagram of a design model according to an embodiment of the disclosure;

FIG. 5 shows simulation results generated by finite element analysis software for the design model in an embodiment of the present application-a curve graph depicting total magnetic field intensity across different survey lines;

FIG. 6 shows simulation results from finite element analysis software for the design model in an embodiment of the present application-a schematic diagram showing calibration results for a lateral position of a passage across different survey lines; and

FIG. 7 shows a comparison diagram between a burial depth calculated on the basis of an embodiment and an actual burial depth of the passage at different burial conditions, according to an embodiment of the present application.

### DETAILED DESCRIPTION

The specific implementation in the embodiments of the disclosure will be clearly and completely described below by reference to the accompanying drawings in the embodiments of the disclosure. Obviously, the embodiments described are only some rather than all embodiments of the disclosure. On the basis of the embodiments of the disclosure, all other embodiments obtained by those ordinary skilled in the art without creative efforts fall within the scope of protection of the disclosure.

In the disclosure, on the basis of the basic principle of mise-a-la-masse method, if a leakage passage exists in a dam, there is a conductivity difference between the leakage passage and the surrounding rock due to the flowing water. By separately deploying a power supply electrode on a downstream face and an upstream face of the dam and applying current signals at different frequencies (below 1 kHz), the current will propagate along a preferential passage with higher conductivity (the leakage passage) within the dam, forming a current loop. According to the Biot-Savart law, the preferential current passage generates a magnetic field in space. By deploying two high-precision three-component magnetic sensors with a height difference of Δh on the dam crest, the total magnetic field anomalies produced by the preferential current passage can be observed to obtain the laterally calibrated position of potential leakage pathway within the dam. Using the laterally calibrated position of the leakage pathway and Δh, the longitudinally calibrated position of the passage can be determined. Combining the spatial localization of the leakage passage with the location of the leakage outlet, the leakage inlet is identified, thereby achieving rapid localization of the dam leakage passage.

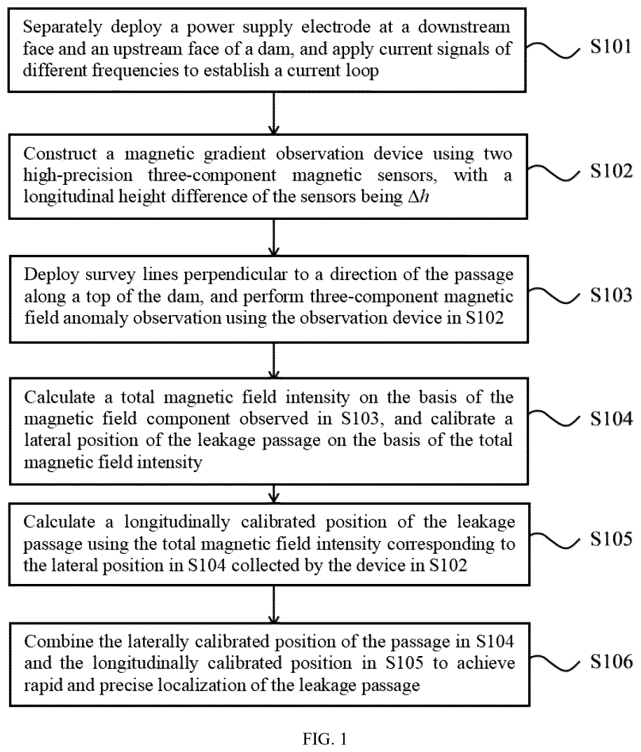

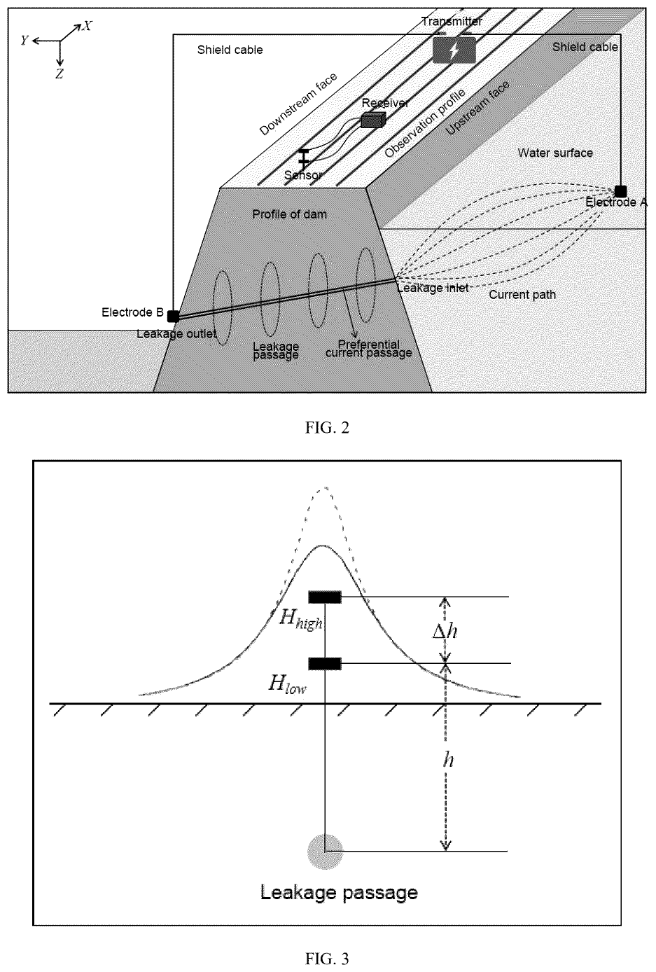

As shown in FIGS. 1-7, an embodiment provides a method for rapid localization of a dam leakage passage based on gradient measurement of a total magnetic field, including the following steps.
Step S101: a uniform current field is established. A power supply electrode is separately deployed at an outlet of a leakage passage on a downstream face of a dam and at a position having a certain distance away from an upstream face of the dam, and current signals of different frequencies are applied to establish a current loop, so as to form a preferential current passage within the leakage passage, as shown in FIG. 2.

According to the Biot-Savart law, the magnetic induction intensity at point P is observed.

$${B}_{s} ( r ) = \frac{μ}{4 π} \int ( σ ( {r}^{′} ) E ( {r}^{′} ) ) \times \frac{r - {r}^{′}}{{\vert r - {r}^{′} \vert}^{3}} d τ$$

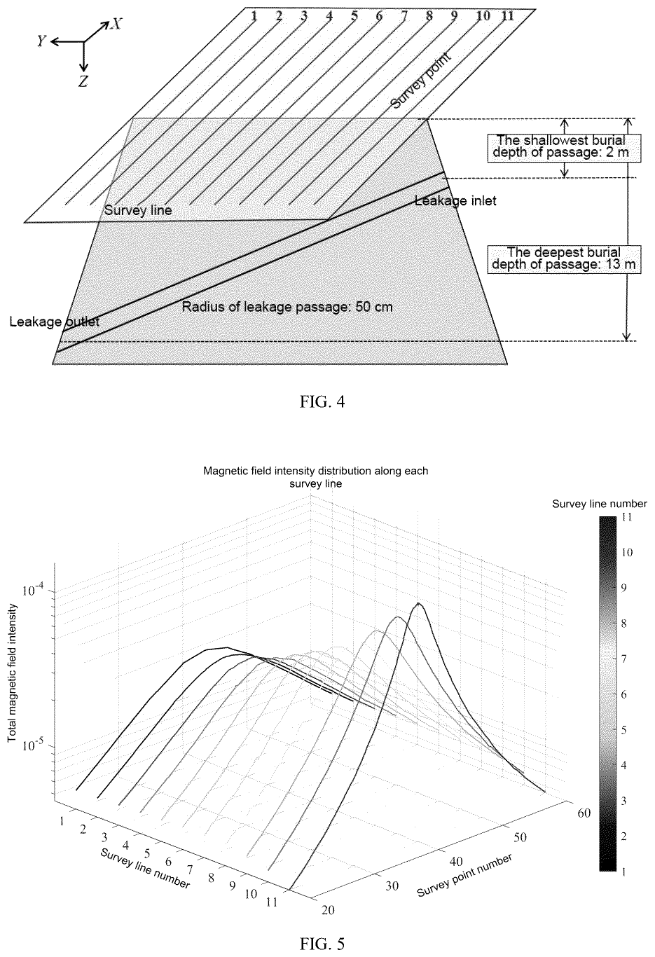

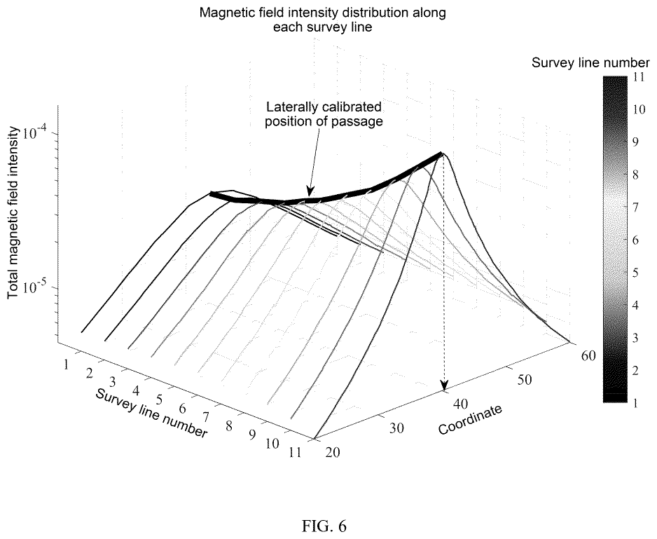

Step S102: a gradient observation device is constructed. A gradient observation device based on high-precision magnetic sensors is designed, with an observation height difference of the magnetic sensors being Δh, and the gradient observation device is utilized to observe a magnetic field component generated by the preferential current passage. The magnetic sensor at a higher position is designated as H_{high}, and a magnetic field measured by a magnetic sensor at a lower position is designated as H_{low}, as shown in FIG. 3.
Step S103: an observation profile is deployed in a direction parallel to the dam, that is, the direction perpendicular to the leakage passage, and three-component magnetic anomaly observation is performed using the gradient observation device in step S102. The direction parallel to the dam is defined as the X-direction, the direction perpendicular to the dam is defined as the Y-direction, and the vertically downward direction is defined as the Z-direction, as shown in FIG. 4.
Step S104: total magnetic field anomaly values at different observation heights are calculated using three-component magnetic anomaly values obtained in step S103, and a lateral position of the leakage passage is calibrated on the basis of a total magnetic field anomaly intensity. When the observation point is directly above the leakage passage, the total magnetic field intensity is the highest, that is, the position corresponding to Hₘₐₓ is the laterally calibrated position of the possible leakage passage, as shown in FIG. 5.
Step S105: a longitudinal burial depth of the leakage passage is calculated on the basis of the total magnetic field anomaly values at different observation heights corresponding to the lateral position of the leakage passage in step S104, and a longitudinal position of the leakage passage can be calibrated, as shown in FIG. 6.

When an observation point is directly above the leakage passage, the total magnetic field intensity observed is expressed as follows:

$$H = \frac{{I}_{0}}{2 π h}$$

where I₀ is the current intensity flowing through the leakage passage, and h is the burial depth of the leakage passage. At this time, the magnetic field intensities at different observation heights are as follows:

$${H}_{l o w} = \frac{{I}_{0}}{2 π h}$$

$${H}_{h i g h} = \frac{{I}_{0}}{2 π ( h + Δ h )}$$

Solving the above equation set can obtain the burial depth h of the leakage passage, with the expression being as follows:

$$h = Δ h \frac{{H}_{h i g h}}{{H}_{l o w} - {H}_{h i g h}}$$

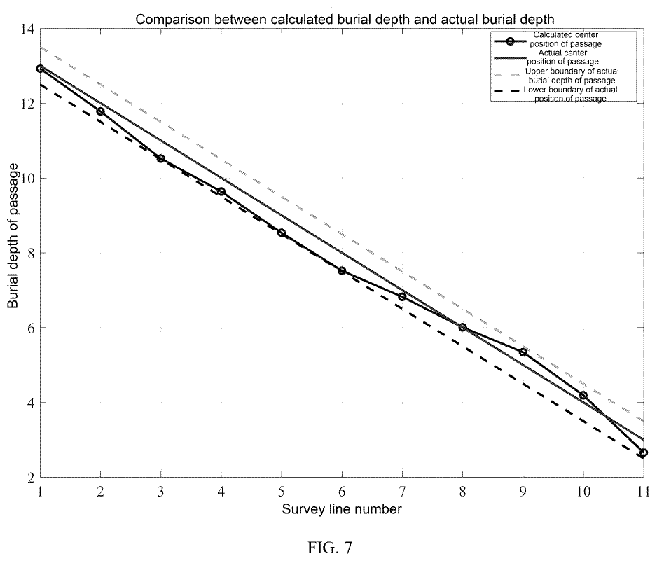

Step S106: rapid and precise localization of the leakage passage can be achieved by combining the laterally calibrated position in step S104 with the longitudinally calibrated position in step S105, as shown in FIG. 7.

In the disclosure, the characteristic that the total magnetic field intensity generated by the leakage passage under the excitation of an artificial source is inversely proportional to the distance is utilized to calculate the burial depth of the leakage passage and locate the leakage passage; moreover, the located leakage passage is combined with the leakage outlet on the downstream face to identify the inlet of the leakage passage, making up for the deficiency that the traditional pseudo-flow field method can only locate the leakage inlet and outlet.

The preferred embodiments of the disclosure disclosed above are used merely to help explain the disclosure. The preferred embodiments are not described in detail, and the disclosure is not limited to the specific embodiment described above. Obviously, many modifications and changes can be made according to the contents of the specification. These embodiments selected and specifically described in the disclosure are to better explain the principle and practical application of the disclosure, so that those skilled in the art can well understand and utilize the disclosure. The disclosure is limited only by the claims and full scope and equivalents thereof.

What is claimed is:

1. A method for rapid localization of a dam leakage passage based on gradient measurement of a total magnetic field, comprising the following steps:
step S101: separately deploying a power supply electrode at an outlet of a leakage passage on a downstream face of a dam and at a position having a certain distance away from an upstream face of the dam, and applying current signals of different frequencies to establish a current loop, so as to form a current passage within the leakage passage;
step S102: designing a gradient observation device based on magnetic sensors, with an observation height difference of the magnetic sensors being Δh, and utilizing the gradient observation device to observe a magnetic field component generated by the current passage;
step S103: deploying an observation profile in a direction perpendicular to the leakage passage, and performing three-component magnetic anomaly observation using the gradient observation device;
step S104: calculating total magnetic field anomaly values at different observation heights using three-component magnetic anomaly values obtained in step S103, and calibrating a lateral position of the leakage passage on the basis of a total magnetic field anomaly intensity;
step S105: calculating a longitudinal burial depth of the leakage passage on the basis of the total magnetic field anomaly values at different observation heights corresponding to the lateral position of the leakage passage in step S104, and calibrating a longitudinal position of the leakage passage, wherein
steps for calibrating the lateral position of the leakage passage are as follows:
calibrating a lateral position of the current passage on the basis of spatial coordinates corresponding to maximum total magnetic field anomaly values Hₘₐₓ at different frequencies; and
steps for calibrating the longitudinal position of the leakage passage are as follows:
calculating the longitudinal burial depth of the leakage passage on the basis of total magnetic field intensity values H_{low} and H_{high} corresponding to the lateral position, with the calculation formula being as follows:
$$h = Δ h \frac{{H}_{h i g h}}{{H}_{l o w} - {H}_{h i g h}}$$
where Δh is a longitudinal height difference between two magnetic sensors, h is a burial depth of the leakage passage, H_{high} is a total magnetic field intensity measured at a higher position, and H_{low} is a total magnetic field intensity measured at a lower position; and
step S106: determining an inlet of the leakage passage by combining the laterally calibrated position in step S104 with the longitudinally calibrated position in step S105, achieving precise localization of the leakage passage.

2. The method for rapid localization of the dam leakage passage based on gradient measurement of the total magnetic field according to claim 1, further comprising utilizing a simultaneous transmission and reception technology to enhance anti-interference capability of data and localization accuracy on the leakage passage.

3. The method for rapid localization of the dam leakage passage based on gradient measurement of the total magnetic field according to claim 1, further comprising determining the inlet of the leakage passage by combining the lateral position and the longitudinal position of the leakage passage with the outlet of the leakage passage.
